(19) United States
(12) Patent Application Publication
(10) Pub. No.: US 2016/0103532 A1
(43) Pub. Date: Apr. 14, 2016

(54) TRANSPARENT CONDUCTIVE FILM, METHOD FOR MAKING THE SAME, AND TOUCH-SENSITIVE SCREEN USING THE SAME

(71) Applicants: INTERFACE OPTOELECTRONIC (SHENZHEN) CO., LTD., Shenzhen (CN); GENERAL INTERFACE SOLUTION LIMITED, Miaoli County (TW)

(72) Inventors: TEN-HSING JAW, Zhubei (TW); CHIN-YANG WU, Zhubei (TW); CHIU-CHI CHEN, Zhubei (TW)

(21) Appl. No.: 14/555,716

(22) Filed: Nov. 28, 2014

(30) Foreign Application Priority Data
Oct. 14, 2014 (CN) 201410540608.3

(51) Int. Cl. G06F 3/047; H05K 3/46; H05K 3/00; G09G 5/00

(52) U.S. Cl. CPC G06F 3/047; G09G 5/003; H05K 3/4661; H05K 3/4664; H05K 3/0014; G09G 2300/0426; G06F 2203/04103

(57) ABSTRACT

A transparent conductive film includes a transparent substrate. A support layer is formed on one surface of the substrate. A surface of the support layer away from the substrate defines grooves formed in a mesh pattern. The grooves include a first groove portion and a second groove portion communicating with the first groove portion. A depth of the first groove portion is less than that of the second groove portion. An ink layer is formed at a bottom of the first groove portion and the second groove portion. A conductive layer is formed on the ink layer and in a mesh pattern. A top of the conductive layer formed in the first groove portion protrudes out of the first groove portion, and the conductive layer formed in the second groove portion is totally received in the second groove portion.

### CROSS-REFERENCE TO RELATED APPLICATIONS

This application is related to co-pending U.S. patent application entitled, “TRANSPARENT CONDUCTIVE FILM, METHOD FOR MAKING THE SAME, AND TOUCH-SENSITIVE SCREEN USING THE SAME”, filed ______ (Atty. Docket No. US56633). The application has the same assignee as the present application. The above-indentified application is incorporated herein by reference.

### FIELD

The subject matter herein generally relates to a transparent conductive film, a touch-sensitive device using the same, and a method for making the same.

### BACKGROUND

Many electronic devices, such as mobile phones, tablet computers, and multimedia players, employ touch-sensitive screens as input interfaces. Typically, the touch-sensitive screen includes a substrate and a transparent conductive film formed on at least one surface of the substrate. The transparent conductive film functions as sensing electrodes capable of identifying touch operations on the touch-sensitive screen, and is usually made of indium tin oxide (ITO).

### BRIEF DESCRIPTION OF THE DRAWINGS

Implementations of the present technology will now be described, by way of example only, with reference to the attached figures.

FIG. 1 is an isometric view of an embodiment of an electronic device having a touch-sensitive screen.

FIG. 2 is an isometric view of an embodiment of the touch-sensitive screen of FIG. 1.

FIG. 3 is an isometric view of an embodiment of a transparent conductive film included in the touch-sensitive screen of FIG. 2.

FIG. 4 is a cross-sectional view taken along line IV-IV of FIG. 3.

FIG. 5 is a flowchart of an embodiment of a method for making a transparent conductive film.

FIG. 6 is an isometric view of an embodiment of a mold core used in the method of FIG. 5.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

Several definitions that apply throughout this disclosure will now be presented.

The term “substantially” is defined to be essentially conforming to the particular dimension, shape, or other feature that the term modifies, such that the component need not be exact. For example, substantially cylindrical means that the object resembles a cylinder, but can have one or more deviations from a true cylinder. The term “comprising,” when utilized, means “including, but not necessarily limited to”; it specifically indicates open-ended inclusion or membership in the so-described combination, group, series and the like.

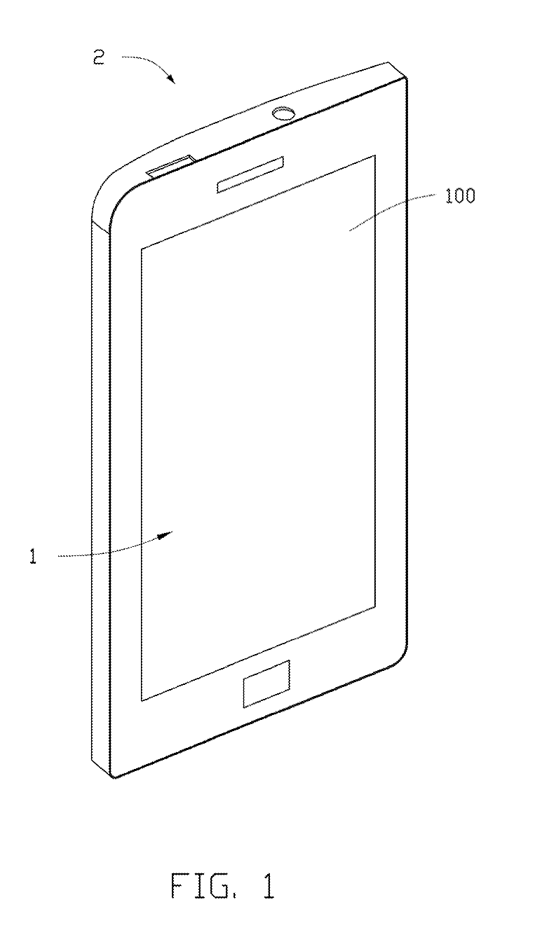

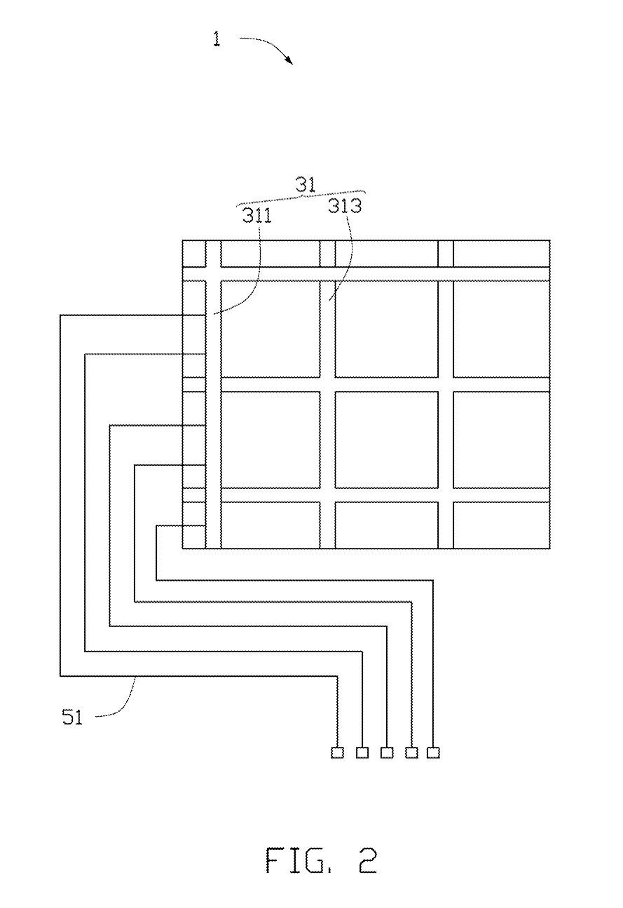

FIGS. 1-2 illustrate an embodiment of a transparent conductive film 100 included in a touch-sensitive screen 1. The touch-sensitive screen 1 can be applied in an electronic device 2, such as a cell phone, a tablet computer, or a media player.

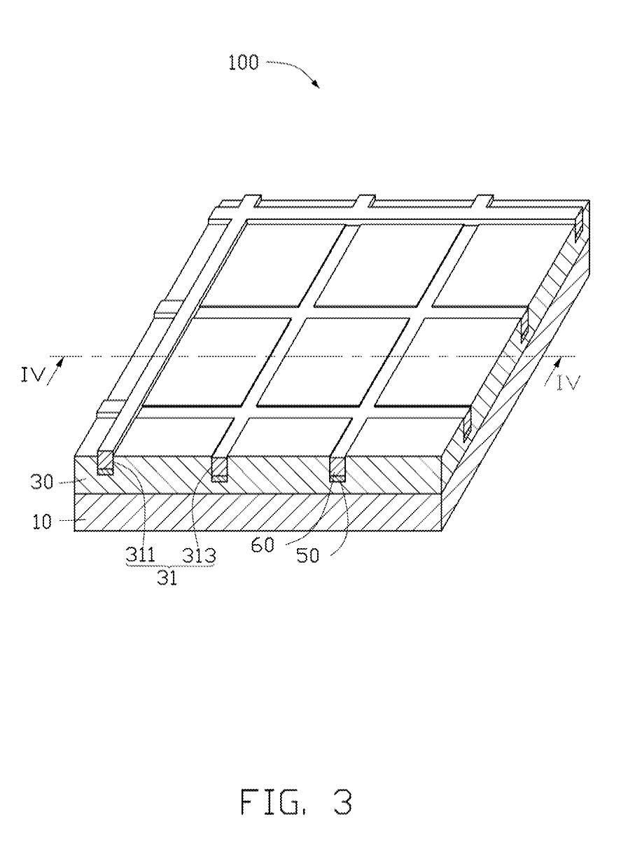

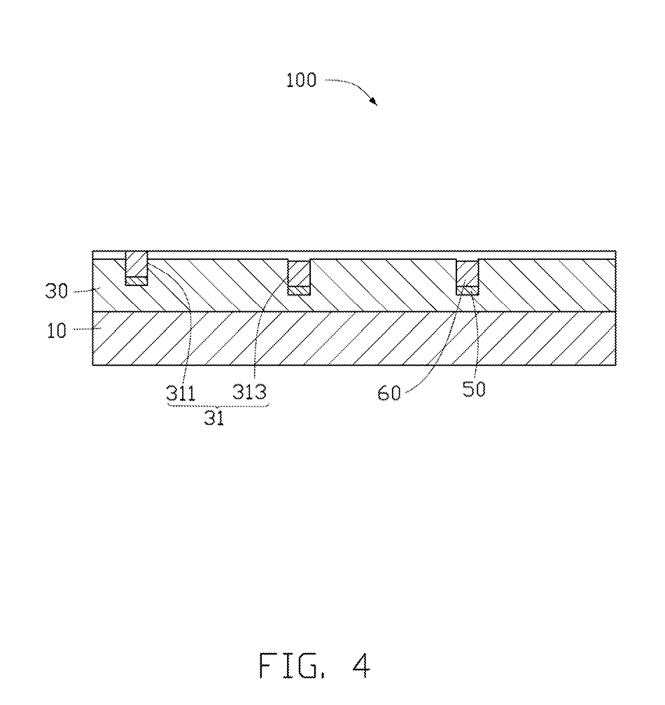

FIGS. 3-4 illustrate that the transparent conductive film 100 includes a transparent and flexible substrate 10. The substrate 10 can be substantially rectangular. In at least one embodiment, the substrate 10 is made of a material selected from a group consisting of polyethylene terephthalate (PET), polyethylene naphthalate (PEN), polyolefin resin, vinyl ester resin, polyetheretherketone (PEEK), polysulfone (PSF), polyether sulphone (PES), polycarbonate (PC), polyamide, polyimide, acrylic resin, and triacetyl cellulose (TAC). The polyolefin resin is selected from a group consisting of polyethylene (PE), polypropylene (PP), polystyrene, and ethylene vinyl acetate (EVA). The vinyl ester resin is selected from a group consisting of polyvinyl chloride, and polyvinylidene chloride. The substrate 10 has a thickness of about 30 μm to about 200 μm.

A support layer 30 is formed on at least one surface of the substrate 10. A surface of each support layer 30 away from the substrate 10 defines a number of grooves 31 formed in a mesh pattern. The grooves 31 define a first groove portion 311 and a second groove portion 313 communicating with the first groove portion 311. A depth of the first groove portion 311 is less than that of the second groove portion 313, and a difference between the depth of the first groove portion 311 and the depth of the second groove portion 313 is at least 0.01 μm. In at least one embodiment, the first groove portion 311 is defined adjacent to and along the peripheral edge of the support layer 30, and the second groove portion 313 is surrounded by the first groove portion 311. In at least one embodiment, the support layer 30 is made of a material selected from a group consisting of thermoplastic polymer, thermosetting polymer, and UV curable polymer. The support layer 30 has a thickness of about 1 μm to about 50 μm.

An ink layer 60 is formed at a bottom of the first groove portion 311 and a bottom of the second groove portion 313. As such, the ink layer 60 is also formed in a mesh pattern. At least one embodiment, the ink layer 60 includes metallic ions selected from a group consisting of palladium (Pd), silver (Ag), titanium (Ti), copper (Cu), zirconium (Zr), or any combination thereof.

A conductive layer 50 is formed on the ink layer 60. As such, the conductive layer 50 is also formed in a mesh pattern. A height of the conductive layer 50 and the ink layer 60 formed in the first groove portion 311 is greater than the depth of the first groove portion 311, namely, a top of the conductive layer 50 formed in the first groove portion 311 protrudes out of the first groove portion 311. In at least one embodiment, the conductive layer 50 protrudes out of the first groove portion 311 by about 0.01 μm to about 2 μm. A height of the conductive layer 50 and the ink layer 60 formed in the second groove portion 313 is less than the depth of the second groove portion 313, namely, the conductive layer 50 formed in the second groove portion 313 is totally received in the second groove portion 313. In at least one embodiment, the conductive layer 50 is made of metal or alloy. The metal is selected from a group consisting of copper (Cu), aluminum (Al), gold (Au), silver (Ag), titanium (Ti), palladium (Pd), chrome (Cr), or any combination thereof.

The conductive layer 50 functions as sensing electrodes capable of identifying touch operation on the touch-sensitive screen 100 and generating corresponding touch signals. Furthermore, the conductive layer 50 can be cost effective compared to the sensing electrode formed of high-price ITO.

FIG. 2 illustrates that the touch-sensitive screen 1 further includes a number of electrode wirings 51 electrically connected to the conductive layer 50 formed in the first groove portion 311. The electrode wirings 51 are capable of delivering the touch signals from the conductive layer 50 to a printed circuit board (PCB, not shown). In at least one embodiment, the electrode wirings 51 are made by the same material as the conductive layer 50.

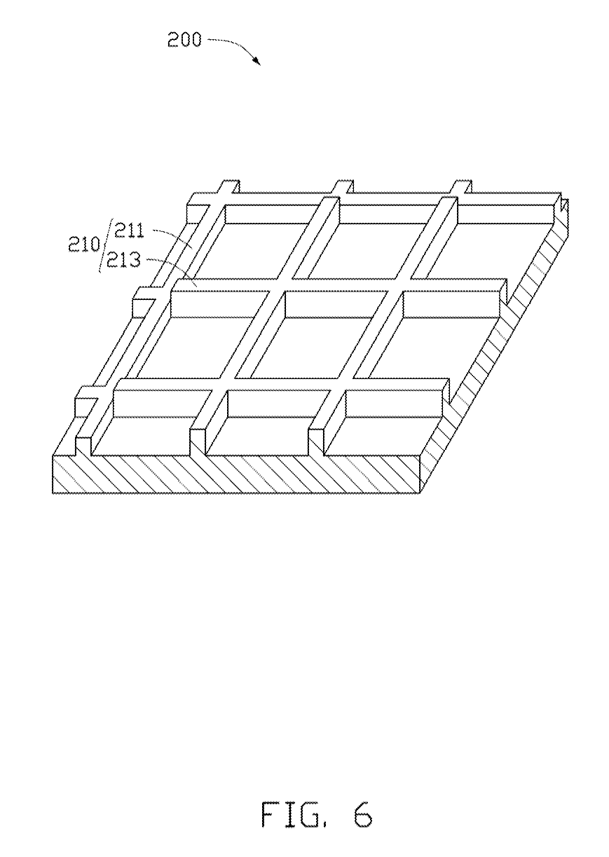

FIGS. 3-6 illustrate that a method for making the transparent conductive film 100 includes the following steps.

In block 51, the transparent substrate 10 is provided.

In block 52, at least one surface of the substrate 10 is coated with a wet transparent resin material (not shown). The transparent resin material includes a material selected from a group consisting of thermoplastic polymer, thermosetting polymer, and UV curable polymer.

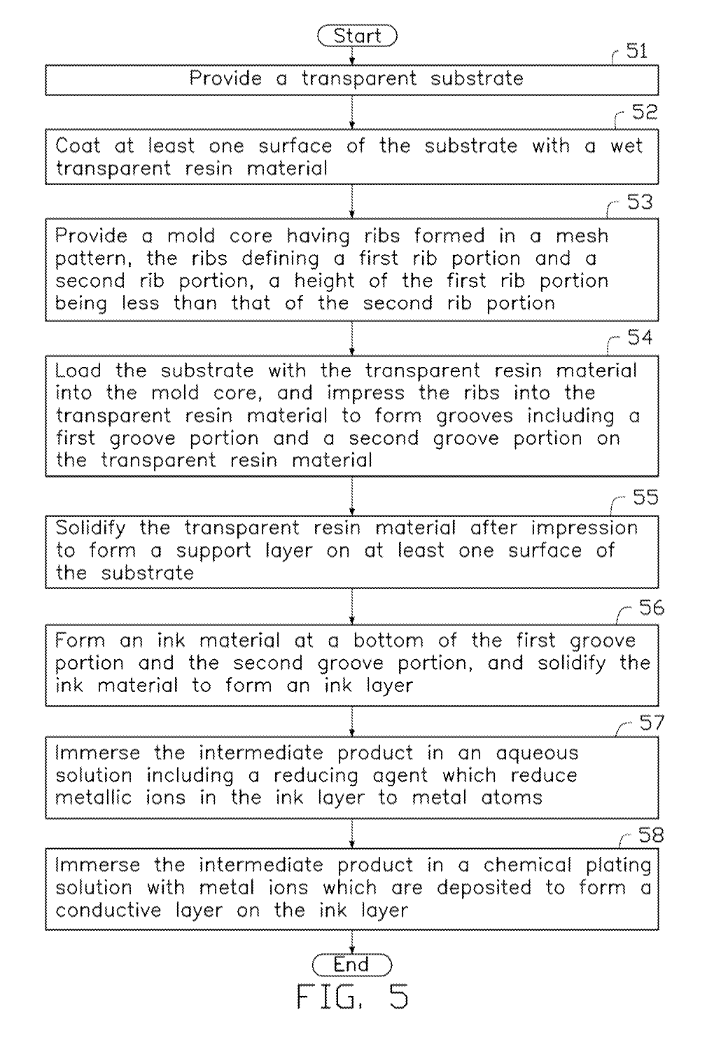

In block 53, a mold core 200 (shown in FIG. 5) is provided. The mold core 200 has a number of ribs 210 formed in a mesh pattern and protruding from a surface of the mold core 200. The ribs 210 define a first rib portion 211 and a second rib portion 213 communicating with the first rib portion 211. A height of the first rib portion 211 is less than that of the second rib portion 213, and a difference between the height of the first rib portion 211 and the height of the second rib portion 213 is at least 0.01 μm.

In block 54, the substrate 10 with the transparent resin material are loaded into the mold core 200. The ribs 210 formed at the mold core 200 are impressed into the transparent resin material at a selected temperature. Then, the grooves 31 including the first groove portion 311 corresponding to the first rib portion 211 and the second groove portion 313 corresponding to the second rib portion 213 are formed on the transparent resin material. In at least one embodiment, the first rib portion 211 is adjacent to the peripheral edge of the mold core 200, and the second rib portion 213 is surrounded by the first rib portion 211.

In block 55, the transparent resin material after impression is solidified to form the support layer 30 on at least one surface of the substrate 10.

In block 56, an ink material is formed at a bottom of the first groove portion 311 and a bottom of the second groove portion 313, and is further solidified to form the ink layer 60. In at least one embodiment, this step may be carried out by printing the ink material on the surface of the support layer 30 defining the groove 31, removing the ink material formed outside the groove 31 by using a scraper for example, and solidifying the remaining ink material to obtain an intermediate product with the ink layer 60 formed at a bottom of the first groove portion 311 and a bottom of the second groove portion 313.

In block 57, the intermediate product is immersing in an aqueous solution including a reducing agent, and the reducing agent can reduce the metallic ions in the ink layer 60 to metal atoms which then function as an accelerant during a subsequent chemical plating reaction. In at least one embodiment, the ink layer 60 includes palladium ions, and the aqueous solution includes sodium hydroxide or sodium pentaborate which reduces the palladium ions to palladium atoms.

In block 58, the intermediate product after being immersed in the aqueous solution is further immersed in a chemical plating solution with metal ions. Then, a chemical plating reaction happens which causes the metal ions in the chemical plating solution to be deposited to form the conductive layer 50 on the ink layer 60. At the same time, the time period for the chemical plating reaction is controlled to cause the conductive layer 50 to protrude out of the first groove portion 311 by about 0.01 μm-2 μm, and the conductive layer 50 to be totally received in the second groove portion 313.

It is to be understood, even though information and advantages of the present embodiments have been set forth in the foregoing description, together with details of the structures and functions of the present embodiments, the disclosure is illustrative only; changes may be made in detail, especially in matters of shape, size, and arrangement of parts within the principles of the present embodiments to the full extent indicated by the plain meaning of the terms in which the appended claims are expressed.

What is claimed is:

1. A transparent conductive film comprising:
a transparent substrate;
a support layer formed on at least one surface of the substrate, a surface of the support layer away from the substrate defining a plurality of grooves formed in a mesh pattern, the grooves including a first groove portion and a second groove portion communicating with the first groove portion, a depth of the first groove portion being less than that of the second groove portion;
an ink layer formed at a bottom of the first groove portion and a bottom of the second groove portion; and
a conductive layer formed on the ink layer and in a mesh pattern, a top of the conductive layer formed in the first groove portion protruding out of the first groove portion, and the conductive layer formed in the second groove portion being totally received in the second groove portion.

2. The transparent conductive film of claim 1, wherein the first groove portion is defined adjacent to a peripheral edge of the support layer, and the second groove portion is surrounded by the first groove portion.

3. The transparent conductive film of claim 1, wherein a difference between the depth of the first groove portion and the depth of the second groove portion is at least 0.01 μm; and the conductive layer protrudes out of the first groove portion by about 0.01 μm to about 2 μm.

4. The transparent conductive film of claim 1, wherein the substrate is made of a material selected from a group consisting of polyethylene terephthalate, polyethylene naphthalate, polyolefin resin, vinyl ester resin, polyetheretherketone, polysulfone, polyether sulphone, polycarbonate, polyamide, polyimide, acrylic resin, and triacetyl cellulose.

5. The transparent conductive film of claim 4, wherein the polyolefin resin is selected from a group consisting of polyethylene, polypropylene, polystyrene, and ethylene vinyl acetate.

6. The transparent conductive film of claim 1, wherein the support layer is made of a material selected from a group consisting of thermoplastic polymer, thermosetting polymer, and UV curable polymer.

7. The transparent conductive film of claim 1, wherein the support layer has a thickness of about 1 μm to about 50 μm.

8. The transparent conductive film of claim 1, wherein the ink layer comprises metallic ions selected from a group consisting of palladium, silver, titanium, copper, zirconium, or any combination thereof.

9. The transparent conductive film of claim 1, wherein the conductive layer is made of metal or alloy.

10. The transparent conductive film of claim 4, wherein the vinyl ester resin is selected from a group consisting of polyvinyl chloride, and polyvinylidene chloride.

11. A touch-sensitive screen comprising:
a transparent conductive film comprising:
a transparent substrate;
a support layer formed on at least one surface of the substrate, a surface of the support layer away from the substrate defining a groove formed in a mesh pattern, the groove including a first groove portion and a second groove portion communicating with the first groove portion, a depth of the first groove portion being less than that of the second groove portion;
an ink layer formed at a bottom of the first groove portion and a bottom of the second groove portion; and
a conductive layer formed on the ink layer and in a mesh pattern, a top of the conductive layer formed in the first groove portion protruding out of the first groove portion, and the conductive layer formed in the second groove portion being totally received in the second groove portion; and
a plurality of electrode wirings electrically connected to the conductive layer formed in the first groove portion, and able to deliver touch signals from the conductive layer to a printed circuit board.

12. The touch-sensitive screen of claim 11, wherein the electrode wirings are made of metal or alloy.

13. A method for making a transparent conductive film, comprising:
providing a transparent substrate;
coating at least one surface of the substrate with a wet transparent resin material;
providing a mold core including a plurality of ribs formed in a mesh pattern and protruding from a surface of the mold core, loading the substrate with the transparent resin material into the mold core, and the ribs impressed into the transparent resin material at a selected temperature;
solidifying the transparent resin material after impression to form a support layer on at least one surface of the substrate, a surface of the support layer away from the substrate defining a plurality of grooves formed in a mesh pattern, the grooves including a first groove portion and a second groove portion communicating with the first groove portion, a depth of the first groove portion being less than that of the second groove portion;
forming an ink layer at a bottom of the first groove portion and a bottom of the second groove portion; and
forming a conductive layer in a mesh pattern on the ink layer, a top of the conductive layer formed in the first groove portion protruding out of the first groove portion, and the conductive layer formed in the second groove portion being totally received in the second groove portion.

14. The method of claim 13, wherein the step of forming a conductive layer in a mesh pattern on the ink layer further comprising:
immersing an intermediate product with the ink layer in an aqueous solution including a reducing agent, and the reducing agent reducing the metallic ions in the ink layer to metal atoms; and
immersing the intermediate product in a chemical plating solution with metal ions, and the metal ions in the chemical plating solution deposited to form the conductive layer on the ink layer.

15. The method of claim 14, further comprising:
controlling a time period for a chemical plating reaction to cause the conductive layer to protrude out of the first groove portion by about 0.01 μm to about 2 μm, and the conductive layer to be totally received in the second groove portion.

16. The method of claim 15, wherein the ribs comprise a first rib portion and a second rib portion communicating with the first rib portion, and a height of the first rib portion is less than that of the second rib portion, and a difference between the height of the first rib portion and the height of the second rib portion is at least 0.01 μm.

17. The method of claim 13, wherein the step of forming an ink layer at a bottom of the first groove portion and a bottom of the second groove portion further comprising:
printing an ink material on the surface of the support layer defining the groove;
removing the ink material formed outside the groove; and
solidifying remaining ink material to obtain the ink layer formed at a bottom of the first groove portion and a bottom of the second groove portion.

18. The method of claim 15, wherein the first rib portion is adjacent to a peripheral edge of the mold core, and the second rib portion is surrounded by the first rib portion.
